(19) United States
(12) Patent Application Publication
(10) Pub. No.: US 2009/0117499 A1
(43) Pub. Date: May 7, 2009

(54) Cleaning solution for immersion photolithography system and immersion photolithograph process using the cleaning solution

(76) Inventors: Se-yeon Kim, Hwaseong-si (KR); Yong-kyun Ko, Osan-si (KR); Sang-mi Lee, Hwaseong-si (KR); Yang-koo Lee, Gwacheon-si (KR); Hun-jung Yi, Suwon-si (KR); Kun-tack Lee, Suwon-si (KR)

Correspondence Address: HARNESS, DICKEY & PIERCE, P.L.C., P.O. BOX 8910, RESTON, VA, 20195, US

(21) Appl. No.: 12/232,594

(22) Filed: Sep. 19, 2008

(30) Foreign Application Priority Data
Sep. 20, 2007 (KR) 10-2007-0095841

(51) Int. Cl. G03F 7/20; C11D 3/20

(52) U.S. Cl. 430/326; 510/109

(57) ABSTRACT

A cleaning solution for an immersion photolithography system according to example embodiments may include an ether-based solvent, an alcohol-based solvent, and a semi-aqueous-based solvent. In the immersion photolithography system, a plurality of wafers coated with photoresist films may be exposed pursuant to an immersion photolithography process using an immersion fluid. The area contacted by the immersion fluid during the exposure process may accumulate contaminants. Accordingly, the area contacted by the immersion fluid during the exposure process may be washed with the cleaning solution according to example embodiments so as to reduce or prevent defects in the immersion photolithography system.

### PRIORITY STATEMENT

This application claims priority under 35 U.S.C. § 119 to Korean Patent Application No. 10-2007-0095841, filed on Sep. 20, 2007 in the Korean Intellectual Property Office (KIPO), the entire contents of which are incorporated herein by reference.

### BACKGROUND

1. Technical Field

Example embodiments relate to a cleaning solution for a photolithography system and a photolithography process using the cleaning solution.

2. Description of the Related Art

During immersion photolithography, the gap between the final lens in the projection optics box and the wafer may be filled with a liquid immersion fluid. The numerical aperture (NA) in the photolithographic process may be defined by the formula below:

NA=n sin α

wherein n refers to the index of refraction, and a refers to the angle formed by the optical axis and the outmost ray of the light entering the objective lens. This formula indicates that the resolution may be improved as the value of the NA gets larger and the wavelength of the light source gets shorter. Thus, one advantage of immersion photolithography may be the enhanced resolution resulting from use of the immersion fluid, thereby achieving a NA larger than 1 (e.g., a NA of about 1.3 or more). When H₂O is used as the immersion fluid, a relatively high refractive index of n=1.44 may be provided, thereby enhancing the resolution and depth of focus (DOF) compared to the resolution and DOF obtained in a conventional “dry” photolithography process.

However, when the wafers are being exposed to the light source during the immersion photolithography process, they are also contacted by the immersion fluid. Consequently, the immersion photolithography system and the wafer may be subjected to defects caused by contact with the immersion fluid. For example, components of materials on the wafer (e.g., photoacid generator (PAG), photoresist film, top barrier coating film) may leach into the immersion fluid during the immersion photolithography process. As a result, the components may accumulate within the photolithography system as defects, thereby lowering system efficiency and causing reverse-contamination of the wafer.

### SUMMARY

Example embodiments relate to a cleaning solution for removing defects that may have accumulated in an immersion photolithography system. A cleaning solution according to example embodiments for an immersion photolithography system may include an ether-based solvent, an alcohol-based solvent, and a semi-aqueous-based solvent. The alcohol-based solvent may include an alkoxyalcohol and/or a diol. The cleaning solution according to example embodiments may further include a basic aqueous solution and/or a corrosion-inhibiting agent. Consequently, when the cleaning solution according to example embodiments is used in an immersion photolithography process, the contaminants that may have accumulated in the immersion photolithography system as a result of coating materials (e.g., photoresist materials, top barrier coating materials) that may have been leached from a previous wafer may be reduced or prevented.

Example embodiments also relate to an immersion photolithography process that may reduce or prevent the reverse-contamination of wafers during the exposure aspect of the process, thus reducing or preventing defects. The reverse-contamination may result from contaminants that may have leached into the immersion photolithography system from previous wafers during an earlier immersion photolithography process.

An immersion photolithography process according to example embodiments may include providing an immersion fluid to an immersion photolithography system, wherein the immersion photolithography system may have one or more wafers coated with a photoresist film. The photoresist film on the one or more wafers may be exposed to a light source. The immersion fluid may be removed after the photoresist film has been exposed to the light source. The area of the immersion photolithography system contacted by the immersion fluid may be cleaned with a cleaning solution including an ether-based solvent, an alcohol-based solvent, and a semi-aqueous-based solvent. Accordingly, the contamination of subsequent wafers during a later immersion photolithography process may be reduced or prevented.

The cleaning aspect of the immersion photolithography process according to example embodiments may include supplying the cleaning solution to the area contacted by the immersion fluid for a predetermined period of time to remove defects from the area. The area supplied with the cleaning solution may also be rinsed with deionized water.

The immersion photolithography process according to example embodiments may further include determining the number of defects on the area contacted by the immersion fluid so as to calculate the predetermined period of time for supplying the cleaning solution. Alternatively, the predetermined period of time for supplying the cleaning solution may be calculated based on the number of wafers exposed in the immersion photolithography system.

According to example embodiments, the reverse contamination of subsequent wafers by contaminants leached from previous wafers during an earlier immersion photolithography process may be reduced or prevented. Additionally, the semi-aqueous-based solvent in the cleaning solution according to example embodiments may provide increased adaptability during an immersion photolithography process that uses a water-based solution for rinsing after cleaning the system. Furthermore, the cleaning solution according to example embodiments may allow the cleaning process to be more in line with the wafer exposure process in the immersion photolithography system. As a result, the time spent cleaning the immersion photolithography system may be decreased, thus enhancing the productivity of the system.

### BRIEF DESCRIPTION OF THE DRAWINGS

The features and advantages of example embodiments may become more apparent upon review of the detailed description in conjunction with the attached drawings.

FIG. 1 is a diagram illustrating a conventional immersion photolithography system.

FIG. 2 is a diagram illustrating the immersion hood of the conventional immersion photolithography system of FIG. 1.

FIG. 3 is a diagram illustrating the immersion hood of FIG. 2 with a closed plate.

FIGS. 4A and 4B are photographs illustrating defects on the surface of a multiporous plate installed within the immersion hood of a conventional immersion photolithography system.

FIG. 5 is a graph illustrating the results of a composition analysis of defects on a multiporous plate within the immersion hood after the exposure process has been performed in a conventional immersion photolithography system.

FIG. 6 is a flowchart illustrating an immersion photolithography process according to example embodiments.

FIG. 7 is a table illustrating the results of cleaning an immersion photolithography system using cleaning solutions according to example embodiments compared to a comparative example using deionized water.

### DETAILED DESCRIPTION OF EXAMPLE EMBODIMENTS

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

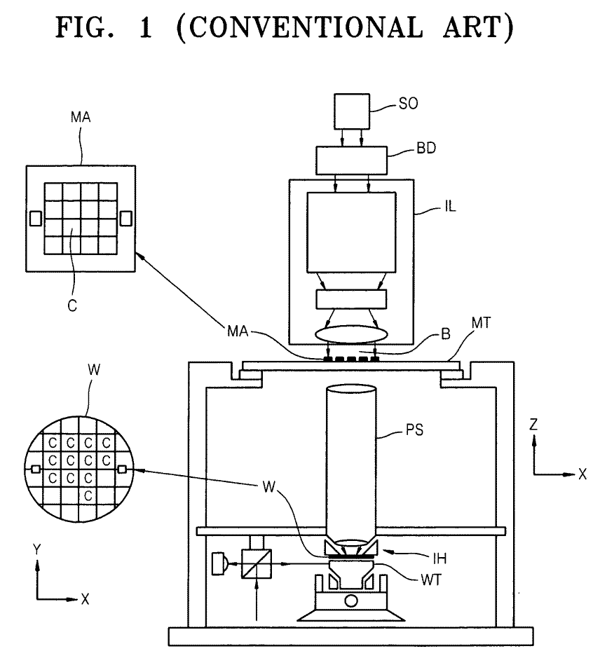

FIG. 1 is a diagram illustrating a conventional immersion photolithography system. Referring to FIG. 1, a conventional immersion photolithography system may include a radiation source SO, a beam delivery system BD, and an illuminator IL emitting a radioactive beam B. A mask table MT may support a mask MA that may be used for patterning, and a wafer table WT may support a wafer W. A projection system PS may project the radiation beam B in the pattern of the mask MA onto a target C of the wafer W.

For example, during the immersion photolithography process, the radiation beam B may be emitted to the mask MA. The portion of the radiation beam B that passes through the mask MA may traverse the projection system PS so as to be focused on the target C of the wafer W. An immersion fluid (not shown) may be supplied by an immersion hood IH to the space between the lower surface of the projection system PS and the wafer W.

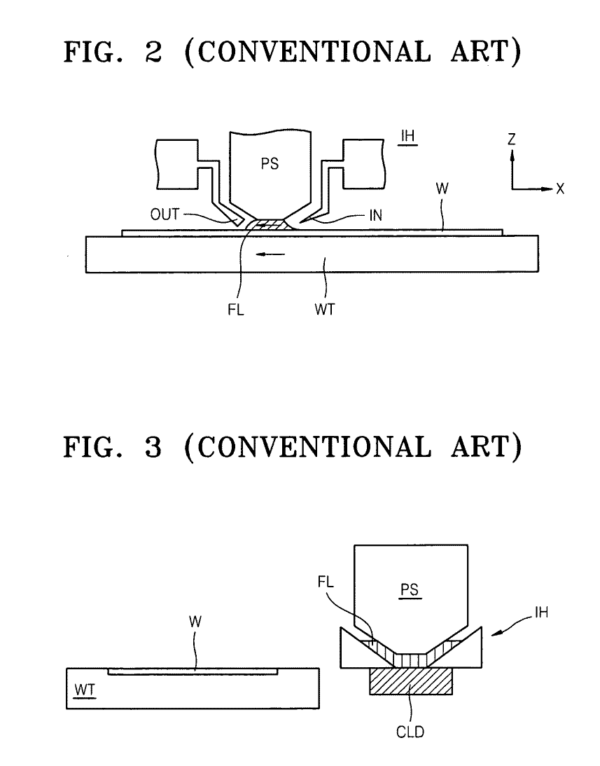

FIG. 2 is a diagram illustrating the immersion hood IH of the conventional immersion photolithography system of FIG. 1. Referring to FIG. 2, the immersion hood IH may supply an immersion fluid FL between the projection system PS and the wafer W. The immersion fluid FL may be supplied from an inlet IN so as to flow over the wafer W in the direction of the movement of the wafer W shown by the arrow adjacent to the projection system PS. The immersion fluid FL may pass through the space between the projection system PS and the wafer W and may be discharged through the outlet OUT.

FIG. 3 is a diagram illustrating the immersion hood IH of FIG. 2 with a closed plate CLD. Referring to FIG. 3, when the wafer table WT slides away from under the projection system PS, the closed plate CLD may slide under the projection system PS to replace the wafer table WT. For example, upon completion of the exposure of the wafer W to the radioactive beam B (FIG. 1), the closed plate CLD and the wafer table WT may horizontally move on approximately the same level so that the closed plate CLD may take up the position under the projection system PS so as to replace the wafer table WT. In the immersion photolithography system shown in FIGS. 1-3, contaminants may accumulate in the immersion hood IH and on the closed plate CLD as a result of repeating the wafer exposure process. Consequently, the accumulation of contaminants may result in the occurrence of defects.

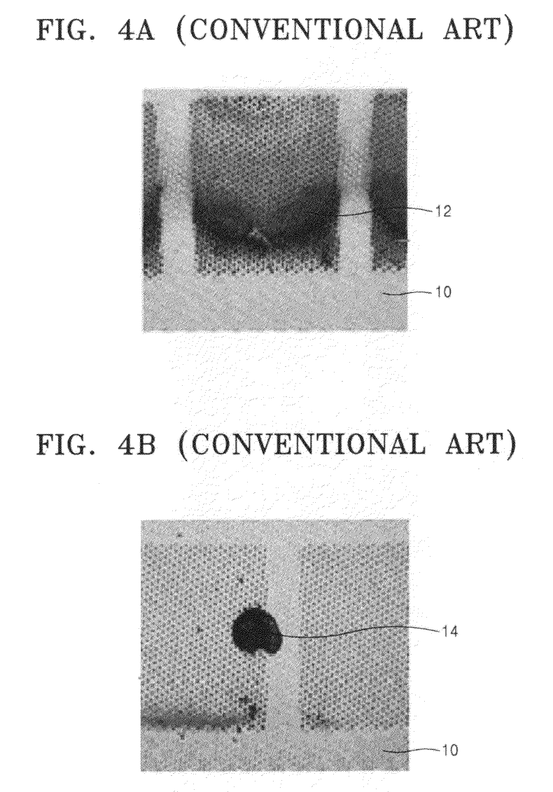

FIGS. 4A and 4B are photographs illustrating defects 12 and 14, respectively, on the top surface of a multiporous plate 10 installed within the immersion hood of a conventional immersion photolithography system. The multiporous plate 10 may be a SPE (single phase extraction)-type discharge device installed on the wafer table WT for releasing the immersion fluid FL within the immersion hood IH. During the immersion photolithography process, contaminants from the film materials of the wafer W may leach into the immersion fluid FL and accumulate on the multiporous plate 10 when the immersion fluid FL is released through the pores of the multiporous plate 10. Similarly, the closed plate CLD may accumulate contaminants during contact with the immersion fluid FL as a result of the closed plate CLD repeatedly moving to replace the wafer table WT under the projecting system PS.

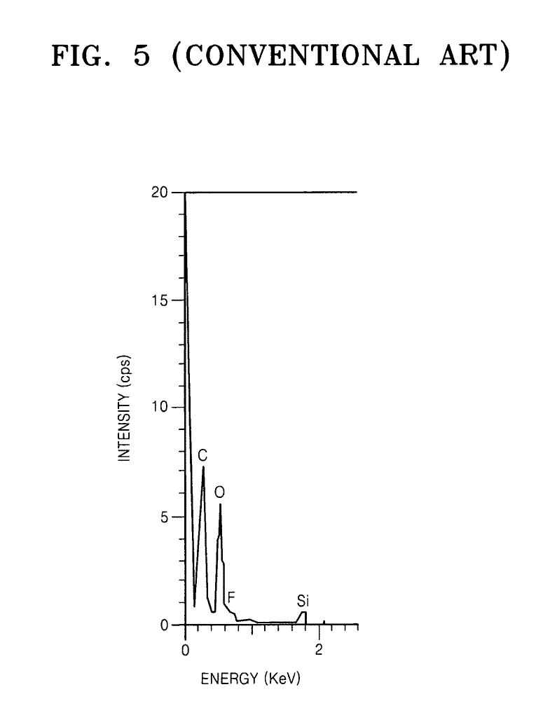

FIG. 5 is a graph illustrating the results of a composition analysis of defects on the multiporous plate 10 within the immersion hood IH after performing continuous exposure processes for a plurality of wafers W using a conventional immersion photolithography system. As shown in FIG. 5, the defects within the immersion hood IH may be mainly composed of C, O, and F. The composition of the defects may be similar or identical to the composition of the photoresist film or the top barrier coating film protecting the photoresist film on the wafer W.

Therefore, example embodiments provide a cleaning solution that may remove contaminants that may have accumulated within the immersion photolithography system (e.g., contaminants leached from the photoresist film or the top barrier coating film of the wafer). The number of defects caused by the contaminants may be proportional to the exposure time and the number of wafers within the immersion hood. Example embodiments also provide an immersion photolithography process for cleaning an immersion photolithography system using the above cleaning solution.

A cleaning solution according to example embodiments may include an ether-based solvent, an alcohol-based solvent, and a semi-aqueous-based solvent. The cleaning solution according to example embodiments may further include at least one of a basic aqueous solution and a corrosion-inhibiting agent. The above components of the cleaning solution according to example embodiments are described in further detail below.

(1) Ether-Based Solvent

In the cleaning solution according to example embodiments, the ether-based solvent may have increased emulsibility, thus swelling the unwanted defects (e.g., organic contaminants accumulated as a result of leaching of the photoresist material and the top barrier coating material) to facilitate their removal. The ether-based solvent may be selected from the group consisting of diethyl ether, ethylene glycol diethyl ether, ethylene glycol butyl ether, diethylene glycol butyl ether, propylene glycol ether, and combinations thereof, although example embodiments are not limited thereto. Rather, other types of ether-based solvents that produce similar results to the results achieved by the above materials may be used.

In the cleaning solution according to example embodiments, if the content of the ether-based solvent exceeds the recommended level, then working with the solution may be unpleasant as a result of a relatively offensive odor caused by certain aromatic groups. On the other hand, if the content of the ether-based solvent is below the recommended level, then the cleaning ability of the solution may be decreased. Consequently, the content of the ether-based solvent may be about 5-40% by weight based on the total weight of the cleaning solution according to example embodiments.

(2) Alcohol-Based Solvent

In the cleaning solution according to example embodiments, the alcohol-based solvent may protect components of the immersion photolithography system during the cleaning process. The components of the immersion photolithography system may be metallic components (e.g., Ni, stainless steel, Al, and the like). The alcohol-based solvent may also have an increased cleaning ability with regard to a variety of defects. The alcohol-based solvent content may be about 1-50% by weight based on the total weight of the cleaning solution.

In the cleaning solution according to example embodiments, the alcohol-based solvent may include alkoxyalcohols and/or diols. Alkoxyalcohols may provide an ion debris-removing effect, and diols may provide a metal surface protecting effect as a result of the two —OH groups. For example, if the alcohol-based solvent includes a combination of an alkoxyalcohol and a diol, the contents of the alkoxyalcohol and the diol may each be about 50% or less by weight based on the total weight of the alcohol-based solvent. Additionally, the contents of the alkoxyalcohol and the diol may each be about 1-25% by weight based on the total weight of the cleaning solution.

The alkoxyalcohol may be at least one of 2-methoxyethanol, 2-ethoxyethanol, 2-butoxyethanol, 2-(2-methoxyethoxy)ethanol, 2-(2-ethoxyethoxy)ethanol, and 2-(2-butoxyethoxy)ethanol. The diol may be at least one of 1,3-butanediol, 1,4-butanediol, and catechol. However, example embodiments are not limited thereto. Various types of alkoxyalcohols and diols with similar effects as the effects achieved by the above materials may be used for the cleaning solution according to example embodiments.

(3) Semi-Aqueous-Based Solution

In the cleaning solution according to example embodiments, a semi-aqueous-based solution may alleviate the relatively offensive odor associated with an ether-type solvent and/or a volatile organic compound (VOC). A semi-aqueous-based solution may also lower the volatility of the alcohol-based solvent. Additionally, a semi-aqueous-based solution may maintain its cleaning abilities under a relatively high contamination load. A semi-aqueous-based solution may provide increased adaptability during an immersion photolithography process that uses a water-based solution for rinsing after a cleaning process using the cleaning solution according to example embodiments. Furthermore, a semi-aqueous-based solution may complement the cleaning ability of a water-based solution in removing organic and ionic defects.

In the cleaning solution according to example embodiments, the semi-aqueous-based solution may include a polar organic solvent. For example, the semi-aqueous-based solution may be at least one of glycol ether, N-methylpyrrolidone, methanol, ethanol, isopropyl alcohol, acetone, acetonitrile, dimethylacetamide, d-limonene, and terpene. The semi-aqueous-based solution may constitute about 20-80% by weight based on the total weight of the cleaning solution.

(4) Basic Aqueous Solution

The cleaning solution according to example embodiments may further include a basic aqueous solution. The basic aqueous solution may contain deionized water and an alkaline solution of about 2% by weight based on the total weight of the basic aqueous solution. When a basic aqueous solution including the above alkaline solution is added to the cleaning solution according to example embodiments, polymeric defects may be more effectively removed compared to when deionized water without the alkaline solution is added. The basic aqueous solution may be about 30-70% by weight based on the total weight of the cleaning solution.

The alkaline solution may be at least one of sodium hydroxide, potassium hydroxide, ammonium hydroxide, and alkyl ammonium hydroxide. For example, tetramethyl ammonium hydroxide (TMAH), tetraethyl ammonium hydroxide, tetrabutyl ammonium hydroxide, tetrapropyl ammonium hydroxide, tetrahexyl ammonium hydroxide, tetraoctyl ammonium hydroxide, benzyltrimethyl ammonium hydroxide, diethyldimethyl ammonium hydroxide, hexadecyltrimethyl ammonium hydroxide, methyltributyl ammonium hydroxide, and the like may be used as the alkaline solution.

(5) Corrosion-Inhibiting Agent

The cleaning solution according to example embodiments may further include a corrosion-inhibiting agent. For example, when there are components made of metal (e.g., Ni, stainless steel) within the immersion photolithography system, the cleaning solution may include a corrosion-inhibiting agent to reduce the possibility of corrosion by the cleaning solution. The corrosion-inhibiting agent may be selected from at least one of phosphates, silicates, nitrites, amine salts, borates, and organic acid salts. The corrosion-inhibiting agent content may constitute about 1% by weight or less based on the total weight of the cleaning solution.

(6) Viscosity of the Cleaning Solution

It may be beneficial to take into account cleaning effectiveness, cleaning time, rinsing efficiency, and the like so as to produce a cleaning solution according to example embodiments having the adequate viscosity. For example, the cleaning solution may have a viscosity of approximately 0.5-1.5 mPa·s to allow flow-type cleaning.

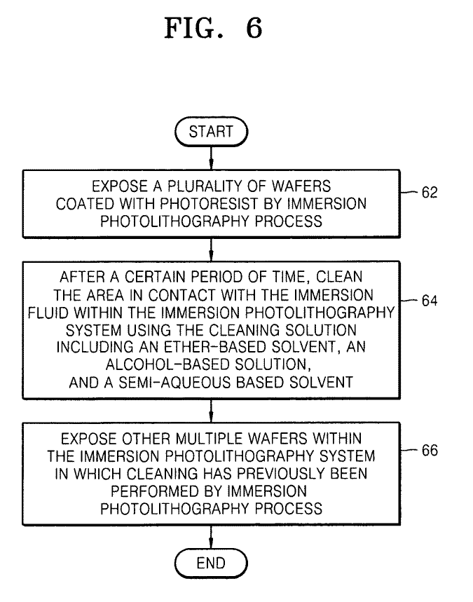

FIG. 6 is a flowchart describing an immersion photolithography process according to example embodiments. Referring to Process 62 of FIG. 6, a plurality of wafers coated with photoresist films in an immersion photolithography system may be exposed to light in an immersion photolithography process using an immersion fluid. In Process 64 of FIG. 6, after a certain period of time, the exposure process of Process 62 may be stopped, and the area contacted by the immersion fluid during the exposure process may be cleaned using a cleaning solution according to example embodiments.

For example, the cleaning solution according to example embodiments may be allowed to flow for a predetermined period of time over the area contacted by the immersion fluid during the exposure process to remove defects from the area. The area may be rinsed of the cleaning solution by allowing deionized water to flow over the area for a predetermined period of time. The defect-removing process and the rinsing process may each be performed for about 5 min-1 hour at room temperature.

The number of defects on the area contacted by the immersion fluid may be determined to calculate the above predetermined periods of time. Alternatively, the above predetermined periods of time may be calculated based on the number of wafers exposed within the immersion photolithography system. In Process 66 of FIG. 6, subsequent wafers coated with photoresist films may be exposed pursuant to an immersion photolithography process in the immersion photolithography system cleaned in Process 64.

To evaluate the cleaning efficiency of cleaning solutions according to example embodiments, cleaning solutions of various compositions were prepared as shown below in Table 1.

TABLE 1

| | | Composition | | | | | | | | | |
|---|---|---|---|---|---|---|---|---|---|---|---|
| | | | | | | | | Semi-aqueous | | | |
| | | Ether-based | | Alcohol-based solvent | | | | based solvent | | Basic aqueous | |
| | | solvent | | 2-ethoxy | | | | (N-methyl | | solution | |
| Type | | (diethyl ether) | | ethanol | | 1,4-butanediol | | pyrrolidone) | | DI | KOH |
| Comparative | 1 | — | | — | | — | | 100 | wt % | — | — |
| Examples | 2 | — | | — | | — | | — | | 99 wt % | 1 wt % |
| | 3 | — | | 3 | wt % | 3 | wt % | — | | 93 wt % | 1 wt % |
| | 4 | 30 | wt % | — | | — | | 70 | wt % | — | — |
| | 5 | — | | 10 | wt % | — | | 90 | wt % | — | — |
| | 6 | — | | — | | 10 | wt % | 90 | wt % | — | — |
| | 7 | 75 | wt % | 15 | wt % | 10 | wt % | — | | — | — |
| Examples | 1 | 25 | wt % | 5 | wt % | 3 | wt % | 75 | wt % | — | — |
| | 2 | 12.5 | wt % | 2.5 | wt % | 1.5 | wt % | 37.5 | wt % | 50 wt % | — |
| | 3 | 12.5 | wt % | 2.5 | wt % | 1.5 | wt % | 37.5 | wt % | 49 wt % | 1 wt % |

Referring to Comparative Examples 1-7 of Table 1, the cleaning solutions were prepared such that the component total for each Comparative Example added up to 100 wt %. On the other hand, for Examples 1-3, the cleaning solutions were prepared such that the component total for each Example (excluding the alcohol-based solvents) added up to 100 wt %. The corresponding amounts of the alcohol-based solvents for Examples 1-3 were then added to the mixture based on the total weight of the mixture.

### Evaluative Example 1

Test wafers were prepared with compositions shown below in Table 2 to evaluate the cleaning efficiency of each cleaning solution. The wafers were produced by forming an ARC (anti-reflective coating) having a thickness of about 2000 Å, a PR (photoresist) having a thickness of about 1500 Å, and a TC (top barrier coating) having a thickness of about 500 Å on a Si substrate. The cleaning efficiencies of the solutions were evaluated by allowing the solutions with the compositions shown in Table 1 to flow over the test wafers for about 30 minutes and identifying the coating materials removed from the test wafers.

The ARC, PR, and TC formed on the Si substrate each display different colors. Therefore, the coating materials removed from the test wafer may be verified by examining the color exposed on the test wafer after treating with the cleaning solution. For example, when the TC is exposed on the outermost surface of a test wafer, then the color is red. When the TC is removed and the PR is exposed, then the color is green. When both the TC and the PR are removed and the ARC is exposed, then the color is yellow.

Table 2 shows the results after treating the test wafers with each of the cleaning solutions in Table 1.

TABLE 2

| Removal | Comparative Examples | | | | | | | Examples | | |
|---|---|---|---|---|---|---|---|---|---|---|
| rate | 1 | 2 | 3 | 4 | 5 | 6 | 7 | 1 | 2 | 3 |
| TC | <10% | <10% | 100% | 100% | <5% | <10% | 100% | 100% | <10% | 100% |
| PR | 0% | 0% | <5% | <90% | 0% | 0% | 100% | 100% | 0% | <90% |
| Color | light | green | green | light | red- | red- | yellow | yellow | red- | light |
| | brown | | | green | brown | brown | | | brown | green |

In Example 1 and Comparative Example 7 of Table 2, the TC and the PR were completely removed such that the ARC was exposed on the top surface of the test wafer. In Example 3 and Comparative Example 4, while the TC was completely removed, the PR was only partially removed, thus showing light green, an intermediate color between the yellow of the ARC and the green of the PR.

### Evaluative Example 2

To evaluate the corrosion level of the metal or metal oxide coatings resulting from each of the cleaning solutions in Table 1, surfaces of Ni, Al₂O₃, and SUS (stainless steel) were treated with the cleaning solutions, and the corrosion levels were examined. The treatment conditions for evaluating each of the cleaning solutions were the same as those in Evaluative Example 1.

Table 3 shows the results after treating Ni, Al₂O₃, and SUS with each cleaning solution of Table 1.

TABLE 3

| | Comparative Examples | | | | | | | Examples | | |
|---|---|---|---|---|---|---|---|---|---|---|
| Corrosion | 1 | 2 | 3 | 4 | 5 | 6 | 7 | 1 | 2 | 3 |
| Ni | ◯ | ◯ | ◯ | ◯ | X | X | X | X | X | X |
| | (>70%) | (<50%) | (<50%) | (<10%) | | | | | | |
| Al₂O₃ | X | ◯ | ◯ | X | X | X | X | X | X | X |
| | | (>90%) | (>50%) | | | | | | | |
| SUS | X | X | X | X | X | X | X | X | X | X |

In Table 3, the occurrence of corrosion is indicated by “O”, and the absence of corrosion is indicated by “X”. As shown in Table 3, Examples 1-3, which were cleaning solutions according to example embodiments, exhibited the absence of corrosion.

### Evaluative Example 3

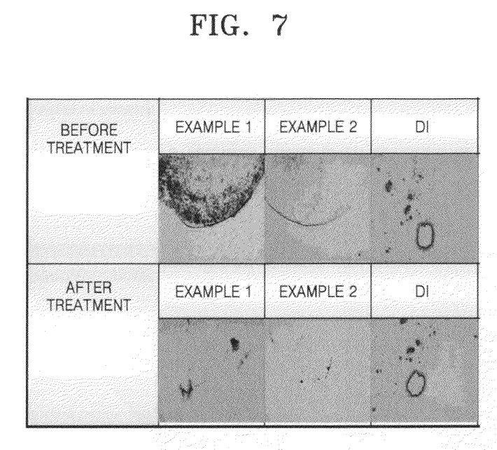

After exposing a plurality of wafers according to an immersion photolithography process using the immersion photolithography system shown in FIGS. 1-3, the resulting defects on the closed plate CLD were cleaned using the cleaning solutions of Examples 1 and 2 in Table 1. A control group involved the treatment of the defects with DI (deionized water). The treatment conditions were the same as those in Evaluative Example 1. As shown in FIG. 7, when the closed plate CLD was cleaned using the cleaning solutions of Examples 1 and 2 according to example embodiments, most of the defects were removed (as opposed to the control group).

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A cleaning solution for an immersion photolithography system, comprising:
an ether-based solvent;
an alcohol-based solvent; and
a semi-aqueous-based solvent.

2. The cleaning solution of claim 1, wherein the ether-based solvent is selected from the group consisting of diethyl ether, ethylene glycol diethyl ether, ethylene glycol butyl ether, diethylene glycol butyl ether, propylene glycol, and combinations thereof.

3. The cleaning solution of claim 1, wherein the ether-based solvent constitutes about 5-40% by weight based on a total weight of the cleaning solution.

4. The cleaning solution of claim 1, wherein the alcohol-based solvent constitutes about 1-50% by weight based on a total weight of the cleaning solution.

5. The cleaning solution of claim 1, wherein the alcohol-based solvent includes an alkoxyalcohol, a diol, or a combination thereof.

6. The cleaning solution of claim 5, wherein the alkoxyalcohol is selected from the group consisting of 2-methoxyethanol, 2-ethoxyethanol, 2-butoxyethanol, 2-(2-methoxyethoxy)ethanol, 2-(2-ethoxyethoxy)ethanol, 2-(2-butoxyethoxy)ethanol, and combinations thereof.

7. The cleaning solution of claim 5, wherein the diol is selected from the group consisting of 1,3-butanediol, 1,4-butanediol, catechol, and combinations thereof.

8. The cleaning solution of claim 5, wherein the alcohol-based solvent includes a combination of an alkoxyalcohol and a diol, the alkoxyalcohol and diol each constituting up to 50% by weight based on a total weight of the alcohol-based solvent.

9. The cleaning solution of claim 1, wherein the semi-aqueous-based solvent is selected from the group consisting of glycol ether, N-methylpyrrolidone, methanol, ethanol, isopropyl alcohol, acetone, acetonitrile, dimethylacetamide, d-limonene, terpene, and combinations thereof.

10. The cleaning solution of claim 1, wherein the semi-aqueous-based solvent constitutes about 20-80% by weight based on a total weight of the cleaning solution.

11. The cleaning solution of claim 1, further comprising:
a basic aqueous solution.

12. The cleaning solution of claim 11, wherein the basic aqueous solution includes deionized water and an alkaline solution, the alkaline solution constituting up to about 2% by weight based on a total weight of the basic aqueous solution.

13. The cleaning solution of claim 11, wherein the basic aqueous solution constitutes about 30-70% by weight based on a total weight of the cleaning solution.

14. The cleaning solution of claim 12, wherein the alkaline solution is selected from the group consisting of sodium hydroxide, potassium hydroxide, ammonium hydroxide, alkyl ammonium hydroxide, and combinations thereof.

15. The cleaning solution of claim 1, further comprising:
a corrosion-inhibiting agent constituting up to about 1% by weight based on a total weight of the cleaning solution.

16. The cleaning solution of claim 15, wherein the corrosion-inhibiting agent is selected from the group consisting of phosphate, silicate, nitrite, amine salt, borate, organic acid salt, and combinations thereof.

17. An immersion photolithography process, comprising:
providing an immersion fluid to an immersion photolithography system, the immersion photolithography system having one or more wafers coated with a photoresist film;
exposing the photoresist film on the one or more wafers to a light source;
removing the immersion fluid; and
cleaning an area of the immersion photolithography system contacted by the immersion fluid with a cleaning solution including an ether-based solvent, an alcohol-based solvent, and a semi-aqueous-based solvent.

18. The immersion photolithography process of claim 17, wherein the cleaning includes
supplying the cleaning solution to the area for a predetermined period of time to remove defects from the area; and
rinsing the area with deionized water.

19. The immersion photolithography process of claim 18, further comprising:
determining the number of defects on the area to calculate the predetermined period of time for supplying the cleaning solution.

20. The immersion photolithography process of claim 18, wherein the predetermined period of time is calculated based on the number of wafers exposed in the immersion photolithography system.
